(19) United States
(12) Patent Application Publication
(10) Pub. No.: US 2026/0090460 A1
(43) Pub. Date: Mar. 26, 2026

(54) INTEGRATED DEVICE PACKAGE LIDS WITH COMPLIANT FEATURES

(71) Applicant: QUALCOMM Incorporated, San Diego, CA (US)

(72) Inventors: Luis Eduardo DE LOS HEROS BEUNZA, San Diego, CA (US); Julian Eduardo CASTILLO CHACON, San Diego, CA (US); Brian ROGGEMAN, Poway, CA (US)

(21) Appl. No.: 18/893,019

(22) Filed: Sep. 23, 2024

(51) Int. Cl. H01L 23/04; H01L 23/373; H01L 23/498; H01L 23/552; H01L 25/065

(52) U.S. Cl. CPC H10W 76/12; H10W 40/25; H10W 42/20; H10W 90/00; H10W 90/701

(57) ABSTRACT

An integrated device package includes a substrate and a die coupled to the substrate. The integrated device package also includes a thermal interface material coupled to the die, and a lid coupled to the substrate and to the thermal interface material. The lid includes a unitary body that includes one or more openings that define a die contact area of the unitary body and one or more compliant members of the unitary body.

### FIELD

Various features relate to integrated device package lids with compliant features.

### DESCRIPTION OF RELATED ART

In state-of-the-art electronic devices, there is generally an expectation that integrated device packages have a small form factor, a low cost, a tight power budget, high performance, and high reliability. These various goals are often in conflict.

For example, modern electronic devices often include integrated circuit (IC) devices (e.g., dies) integrated within integrated device packages. The IC packaging serves as an interface between IC dies and the external environment. IC packaging also protects the IC components mechanically, facilitates heat dissipation, and establishes electrical connections to the outside world (e.g., other components of the electronic device). Over the years, as ICs have become more complex and powerful, IC packaging has also become more complex. To illustrate, more complex ICs often have more external interconnects (e.g., contacts) that must be serviced by the IC packaging, resulting in more expensive and larger packaged IC devices.

Efforts to reduce dimensions of the IC packaging can reduce reliability of the packaged IC device. For example, IC packages generally include a package substrate which adds to the overall dimensions (thickness and footprint) of the packaged IC device. Reducing the thickness of the package substrate can therefore reduce the total size of the packaged IC device; however, thinner package substrates are associated with increased risk of warpage and/or other stresses due to differences in thermal expansion coefficients between materials of the packaged IC device (e.g., the die(s), the substrate, a lid, etc.). Such warpage and stresses can cause reliability issues such as die cracking, solder joint failure, and delamination of thermal interface materials.

As another example, traditionally, packaged IC devices include a lid. Such lids are typically coupled to the package substrate, and they serve the dual purpose of protecting the IC and dissipating heat. Often, lids are formed of rigid materials with high thermal conductivity (mostly metals). Rigidness of the lid of a packaged IC device can exacerbate the stresses described above.

### SUMMARY

Various features relate to integrated circuit devices.

One example provides an integrated device package that includes a substrate and a die coupled to the substrate. The integrated device package also includes a thermal interface material coupled to the die, and a lid coupled to the substrate and to the thermal interface material. The lid includes a unitary body that includes one or more openings that define a die contact area of the unitary body and one or more compliant members of the unitary body.

One example provides a device that includes a printed circuit board and an integrated device package electrically coupled to the printed circuit board. The integrated device package includes a substrate and a die coupled to the substrate. The integrated device package also includes a thermal interface material coupled to the die, and a lid coupled to the substrate and to the thermal interface material. The lid includes a unitary body that includes one or more openings that define a die contact area of the unitary body and one or more compliant members of the unitary body.

Another example provides a method of fabrication that includes coupling a die to a substrate and coupling a thermal interface material to the die. The method also includes coupling a lid to the substrate and to the thermal interface material. The lid includes a unitary body that includes one or more openings defining a die contact area of the unitary body and one or more compliant members of the unitary body.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view, and various drawings include hatching to show contrast between a surface of a lid and openings in the lid.

FIG. 1A illustrates a schematic plan view of an example of a lid for an integrated device package.

FIG. 1B illustrates a schematic cross-sectional view of an example of a device that includes an integrated device package that includes the lid of FIG. 1A.

FIG. 1C illustrates a schematic cross-sectional view of another example of a device that includes an integrated device package that includes the lid of FIG. 1A.

FIG. 1D illustrates a schematic cross-sectional view of another example of a device that includes an integrated device package that includes the lid of FIG. 1A.

FIG. 2 illustrates a schematic plan view of another example of a lid for an integrated device package.

FIG. 3 illustrates a schematic plan view of another example of a lid for an integrated device package.

FIG. 4 illustrates a schematic plan view of another example of a lid for an integrated device package.

FIG. 5 illustrates a schematic plan view of another example of a lid for an integrated device package.

FIG. 6 illustrates a schematic plan view of another example of a lid for an integrated device package.

FIG. 7 illustrates a schematic plan view of another example of a lid for an integrated device package.

FIG. 8A illustrates a schematic plan view of another example of a lid for an integrated device package.

FIG. 8B illustrates a schematic cross-sectional view of an example of a device that includes an integrated device package that includes the lid of FIG. 8A.

FIG. 9 illustrates a schematic plan view of another example of a lid for an integrated device package.

FIG. 10 illustrates a schematic plan view of another example of a lid for an integrated device package.

FIG. 11 illustrates a schematic plan view of another example of a lid for an integrated device package.

FIG. 12 illustrates a schematic plan view of another example of a lid for an integrated device package.

FIG. 13 illustrates a schematic plan view of another example of a lid for an integrated device package.

FIG. 14 illustrates a schematic plan view of another example of a lid for an integrated device package.

FIG. 15 illustrates a schematic plan view of another example of a lid for an integrated device package.

FIG. 16 illustrates a schematic plan view of another example of a lid for an integrated device package.

FIG. 17A illustrates a schematic plan view of another example of a lid for an integrated device package.

FIG. 17B illustrates a schematic cross-sectional view of an example of a device that includes an integrated device package that includes the lid of FIG. 17A.

FIG. 18A illustrates a schematic plan view of another example of a lid for an integrated device package.

FIG. 18B illustrates a schematic cross-sectional view of an example of a device that includes an integrated device package that includes the lid of FIG. 18A.

FIG. 19A illustrates a schematic plan view of another example of a lid for an integrated device package.

FIG. 19B illustrates a schematic cross-sectional view of an example of a device that includes an integrated device package that includes the lid of FIG. 19A.

FIG. 20A illustrates a schematic plan view of another example of a lid for an integrated device package.

FIG. 20B illustrates a schematic cross-sectional view of an example of a device that includes an integrated device package that includes the lid of FIG. 20A.

FIG. 20C illustrates a schematic cross-sectional view of an example of a device that includes an integrated device package that includes the lid of FIG. 20A.

FIG. 21A illustrates a first part of an exemplary sequence for fabricating an exemplary device that includes an integrated device package that includes an example of the lid as described herein.

FIG. 21B illustrates a second part of an exemplary sequence for fabricating an exemplary device that includes an integrated device package that includes an example of the lid as described herein.

FIG. 22 illustrates an exemplary flow diagram of a method of fabricating an integrated device package that includes an example of a lid as described herein.

FIG. 23 illustrates various electronic devices that integrate a device that includes an example of a lid as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, various structures may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

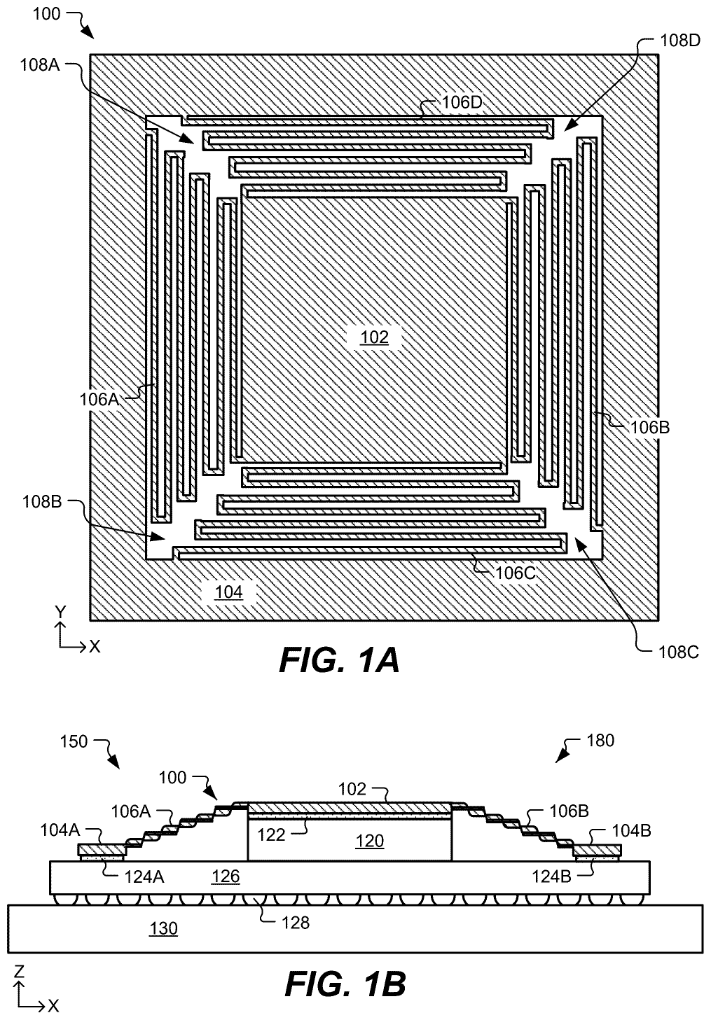

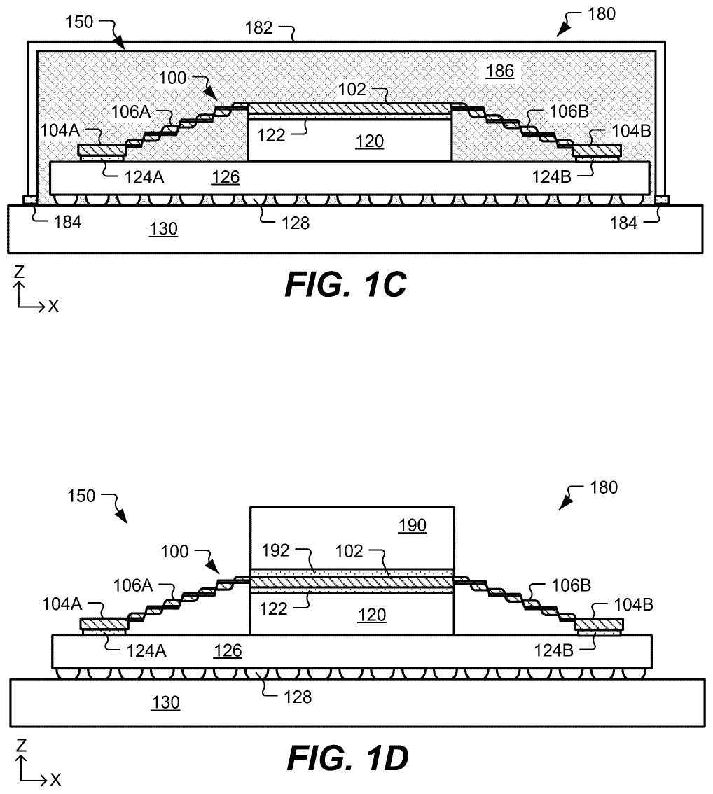

In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1B, multiple compliant members are illustrated and associated with reference numbers 106A and 106B. When referring to a particular one of these compliant members, such as a compliant member 106A, the distinguishing letter “A” is used. However, when referring to any arbitrary one of these compliant members or to these compliant members as a group, the reference number 106 is used without a distinguishing letter.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and does not indicate a particular vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

In general, integrated device packages (also commonly called “chip packages” or “integrated circuit (IC) packages”) include one or more components (generally including at least one die or other integrated circuit device) attached to a substrate. The substrate includes conductors to electrically couple the components of the integrated device package to off-package components via a printed circuit board. For example, off-package electrical connections can be formed using a ball grid array (BGA) of the substrate of the integrated device package. The integrated device package can also include features to protect the packaged components from various hazards, such as moisture, dust, and vibration.

While packaging such components can improve reliability and durability of packaged components, packaging of integrated devices can lead to other challenges. For example, an integrated device package that includes a particular die is necessarily larger than the bare die alone would be.

As another example, integrated device packages are formed from a variety of materials, which generally have different coefficients of thermal expansion (CTE). As a result, when an integrated device package is subjected to heating, differences in CTE cause the various materials to expand by different amounts, which can introduce significant stresses on components of the integrated device package and can lead to various failure modes, such as warpage, delamination, or cracking.

As another example, packaging an IC device (e.g., a die) can make removal of heat from the IC device more challenging. Heat generated due to operation of the IC devices can limit performance of the IC device. In some implementations, performance of the IC device may be throttled to control the temperature of the IC device if the rate of heat removal from the IC device is not sufficient to control the temperature.

Many integrated device packages use a lid to help with one or more of these challenges. Generally, the lid is attached to the substrate of the integrated device package and covers components of the integrated device package. The lid is usually machined or stamped from a material with high thermal conductivity (e.g., metal) so that the lid can act as a heat spreader for the integrated device package, which can improve the rate of heat removal from packaged components of the integrated device package. The lid is generally also fairly rigid to resist warpage.

In a lidded integrated device package, the lid may be thermally coupled to one or more packaged components by a thermal interface material (TIM), such as a thermal paste. Warpage can lead to delamination of the lid from the TIM, delamination of the TIM from the packaged component(s), or both. Such delamination can cause thermal performance degradation of the integrated device package.

Integrated device package lids that include compliant members are disclosed. The disclosed lids can be manufactured using low cost techniques, such as stamping or machining, similar to techniques used for conventional lids. When the compliant members of disclosed lids are deflected (e.g., when the lid is installed on an integrated device package), the compliant members act as springs to generate a bias force. The bias force pushes a die contact area of the lid toward the components of the integrated device package. Thus, in the presence of uneven substrate warpage the disclosed lid reduces the likelihood of delamination. For example, the disclosed lid conforms to the local conditions and self-levels by disproportionate reaction load caused by disproportionate lid deflection. The effect is that the lid dampens the warpage to remain in contact with the TIM.

Additionally, the bias forces tend to resist warpage of a substrate of the integrated device package. Thus, the disclosed lids can address (e.g., reduce or eliminate) various problems that can arise from use of conventional lids. As a result, the disclosed lids can improve reliability of integrated device packages. The disclosed lids also provide other benefits, such as facilitating removal of heat by acting as a heat spreader. The disclosed lids apply a compressive force to the TIM and die. Generally, the higher the force applied to a thermal paste (e.g., the TIM), the better the thermal performance of the thermal paste. Thus, the disclosed lids improve thermal performance of the TIM. In some cases, the disclosed lids can also apply rotational forces that can improve contact between the lid and the TIM, between the TIM and packaged components, or both, which can further improve heat transfer relative to conventional lids.

The magnitudes and directions of bias forces generated by a lid of the present disclosure can be tuned (during fabrication or design) to the specific needs of the integrated device package. For example, the positions, geometry, and dimensions of the compliant members can be selected to provide desired bias forces when installed in an integrated device package. Thus, the disclosed lids provide package designers with design options that are not available when a conventional lid is used.

### Exemplary Integrated Device Package Lids and Devices

FIG. 1A illustrates a schematic plan view of a lid 100 for an integrated device package 150 (illustrated as a lid for a flip-chip ball grid array (FCBGA) package). FIGS. 1B-1D illustrate schematic cross-sectional views of various examples of a device 180 that includes the integrated device package 150. In particular, FIG. 1B illustrates the integrated device package 150 coupled to a printed circuit board (PCB) 130 to form the device 180. FIG. 1C illustrates the integrated device package 150 coupled to the PCB 130 and enclosed within an electromagnetic shield lid 182 to form the device 180. FIG. 1D illustrates the integrated device package 150 coupled to the PCB 130 and to a heat sink 190 (via TIM 192). The various examples illustrated in FIGS. 1B-1D are merely illustrative and should not be considered limiting.

In each of FIGS. 1B-1D, the integrated device package 150 is electrically coupled to the PCB 130. For example, in FIGS. 1B-1D, the integrated device package 150 includes one or more dies (e.g., exemplary die 120) electrically coupled to a substrate 126 and covered by the lid 100. In this example, the substrate 126 includes a plurality of conductors (e.g., a ball grid array 128) that, together with conductors of the substrate 126 define electrical pathways between the die 120 and the PCB 130.

In some embodiments, (such as in the example of FIG. 1C), the integrated device package 150 is at least partially encapsulated within a mold compound 186. Optionally, in some embodiments, the integrated device package 150 can also, or alternatively, be covered by an electromagnetic shield lid 182. In such embodiments, the electromagnetic shield lid 182 can be coupled to the PCB 130 using adhesive 184 or solder. In general, the electromagnetic shield lid 182 is configured to act as a Faraday cage or ground-plane to impede electromagnetic fields. Accordingly, the electromagnetic shield lid 182 is generally a solid metal sheet that is formed (e.g., bent or stamped) to define a cover for the integrated device package 150. If the electromagnetic shield lid 182 includes openings, such as a mesh, dimensions of openings of the mesh should be sized appropriately for the wavelength of the electromagnetic waveform(s) to be blocked. To illustrate, generally, openings of the mesh should be no larger than a fraction (e.g., about one tenth) of the wavelength of the electromagnetic waveform(s) to be blocked. In some embodiments, the electromagnetic shield lid 182, the mold compound 186, or both, are omitted. In some such embodiments, the lid 100 can be configured to provide electromagnetic shielding for the die 120, as described further below.

Many of the features of the device 180 illustrated in FIGS. 1B-1D are optional and are illustrated primarily to provide context for aspects of the disclosure. For example, as explained above, in some embodiments, the device 180 does not include the mold compound 186 and/or the electromagnetic shield lid 182 of FIG. 1C. As another example, in some embodiments, the device 180 does not include the heat sink 190 of FIG. 1D. Further, in some examples, the device 180 of FIGS. 1B-1D includes one or more additional devices or components electrically coupled to the PCB 130. To illustrate, one or more additional integrated device packages, one or more discrete components (e.g., capacitors, inductors, resistors, switches, etc.) can be coupled to the die 120 by electrical pathways of the PCB 130 and the integrated device package 150. Additionally, or alternatively, the integrated device package 150 can include additional components or features that are not shown in FIGS. 1B-1D. To illustrate, the integrated device package 150 can include more than one die. When the integrated device package 150 includes two or more dies, the dies can be stacked one on another, or can be disposed side-by-side on the substrate 126. The integrated device package 150 can also, or alternatively, include other components, such as passive components, interposers, etc.

Each of the dies (e.g., the die 120 and any other die included in the device 180) can include integrated circuitry, such as a plurality of transistors and/or other circuit elements arranged and interconnected to form logic cells, memory cells, etc. In some embodiments, the die 120 can include one or more chiplets. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. Further, the dies may include or correspond to particular integrated circuit (IC) devices that can be arranged and interconnected as a three-dimensional (3D) IC device. In some implementations, the dies include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies. Additionally, or alternatively, the dies may include or be operated as a memory, such as a static random-access memory (SRAM), a dynamic random-access memory (DRAM), flash memory, read-only memory (ROM), programmable read-only memory (PROM), erasable programmable read-only memory (EPROM), cache memory, electrically erasable programmable read-only memory (EEPROM), a solid-state storage device (SSD), or a combination thereof.

Further, the device 180 can be integrated with or included within a wide variety of other devices. For example, two or more integrated device packages 150 can be coupled to the PCB 130 side-by-side with one another and, optionally, covered by a single electromagnetic shield lid 182 or coupled to a single heat sink 190. Further, a device that includes one or more of the devices 180 or the integrated device packages 150 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the devices 180 or the integrated device packages 150 can operate as any of these components (or a combination of these components) that includes active circuitry.

In a particular aspect, the lid 100 is a unitary body (e.g., a single sheet of metal) including one or more openings 108 (such as opening 108A, 108B, 108C, and 108D in FIG. 1A) defining a die contact area 102, a substrate contact area 104, and one or more compliant members 106 (such as compliant members 106A, 106B, 106C and 106D in FIG. 1A) disposed between the die contact area 102 and the substrate contact area 104. The compliant member(s) 106 are separated by opening(s) 108 of the unitary body. The substrate contact area 104 is configured to be coupled to the substrate 126. For example, the substrate contact area 104 can be bonded to the substrate 126 using a bond material 124, such as an adhesive or solder. As another example, the substrate contact area 104 can be coupled to the substrate 126 via fasteners, or protrusions of the substrate contact area 104, positioned in plated-through holes or similar assembly techniques.

The lid 100 is configured to facilitate removal of heat from the die 120 (e.g., as a heat spreader), to resist warpage of the substrate 126, or both. For example, differences in the coefficient of thermal expansion (CTE) among materials of the integrated device package 150 can cause the substrate 126 to tend to warp. Such warping can cause reliability and/or durability concerns for the device 180. To illustrate, warpage can cause electrical faults (e.g., opens or shorts) among electrical connections between the die 120 and the substrate 126, among electrical connections between the substrate 126 and the PCB 130, or both. Further, normal operation of the die 120 generates heat, which should be managed to reduce the likelihood of warpage and to improve performance of the die 120. Warpage can also occur due to various device fabrication processes. For example, the integrated device package 150 can be subjected to significant heating in order to reflow solder during various stages of fabrication. Such heating during fabrication can also result in warpage, which is mitigated by the lid 100.

To encourage movement of heat from the die 120 to the lid 100, the lid 100 is coupled to the die 120 using thermal interface material 122. Conventional integrated device lids tend to be substantially rigid. As a result, when such conventional integrated device lids receive heat from a die or are disposed in a hot ambient environment, CTE differences between the die and the conventional integrated device lid can induce stresses that can result in delamination of the conventional integrated device lid from the TIM and die, warpage of the integrated device package, or both.

In contrast to conventional integrated device lids, the compliant members 106 of the lid 100 enable the die contact area 102 to move relative to the substrate contact area 104 to release thermally (or mechanically) induced stresses. Such compliance of the lid 100 has several benefits. One benefit is that the lid 100 is less likely to delaminate from the TIM 122 (or the TIM 192 if present) than are the conventional integrated device lids described above. For example, stresses induced due to differences in CTE can be mitigated by flexing of one or more of the compliant members 106. Another benefit of the lid 100 is that flexing of the compliant members 106 induces spring forces (e.g., according to Hook's law). Thus, warpage of the integrated device package 150 that results in flexion of one or more of the compliant members 106 tends to be resisted by spring forces that are induced in the lid 100 by the warpage. Further, in spite of such warpage, the lid 100 is able to remain in thermal contact with the die 120.

The compliant members 106 of the lid 100 include or correspond to arms of the unitary body that extend from multiple sides of the die contact area 102. The arms can have different configurations in different embodiments, as described further below. As one example, as shown in FIG. 1A, each of the compliant members 106 of the lid 100 can define a meandering path between the die contact area 102 and the substrate contact area 104 of the unitary body. The meandering paths of the compliant members 106 enable the lid 100 to flex along a Z-axis illustrated in FIG. 1B (and to a lesser extent along an X-axis and a Y-axis illustrated in FIG. 1A).

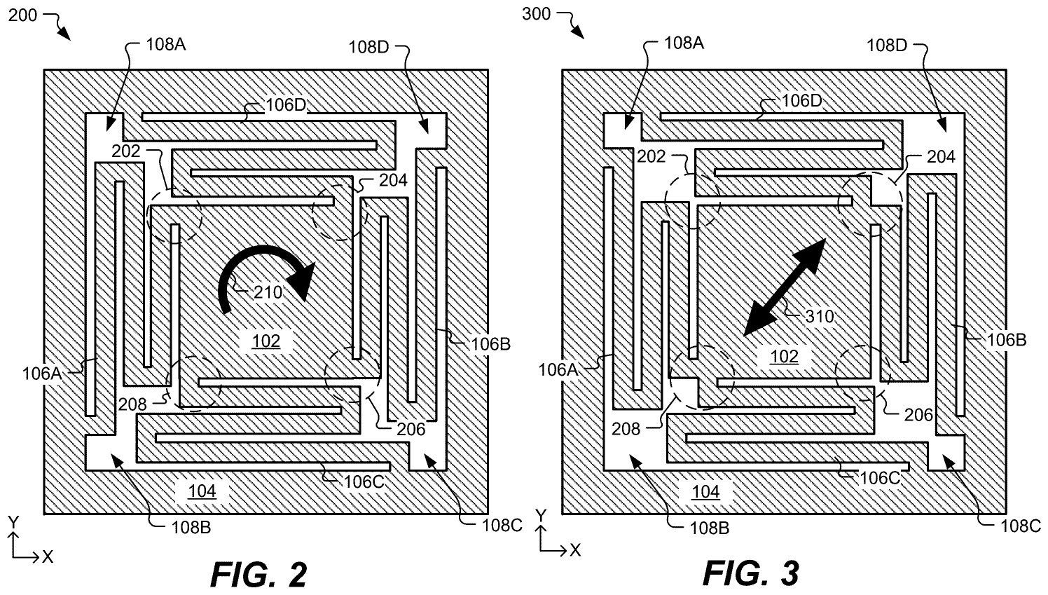

The compliant member(s) 106 can be defined in the unitary body of the lid 100 by forming the opening(s) 108 in the unitary body to separate and define adjacent arms. For example, in FIG. 1A, the openings 108A and 108D define the meandering path of the compliant member 106D as well as separating the compliant member 106D from compliant members 106A and 106B that are adjacent to the compliant member 106D. The openings 108 are spaced and sized to provide target bias forces between the thermal interface material 122 and the substrate 126 based on material properties of the unitary body. To illustrate, FIG. 2 shows an example of a lid 200 in which the openings 108 define compliant members 106 that have fewer turns and wider X-, Y-dimensions than the compliant members 106 of the lid 100 of FIG. 1A. As a result, the compliant members 106 of FIG. 2 will tend to be less flexible (e.g., provide more bias force to resist deformation) than the compliant members 106 of FIG. 1A. In some embodiments, the openings 108 can be spaced and sized to enable the lid 100 to provide electromagnetic shielding for the die 120.

In some examples, the unitary body has a substantially uniform thickness (e.g., along the Z-axis). In such examples, a thickness of the die contact area 102 is substantially equal to a thickness of one or more of the compliant member(s) 106 and is substantially equal to a thickness of the substrate contact area 104. In other examples, the thickness of the unitary body is different at various locations. To illustrate, the thickness of the die contact area 102 is different from the thickness of one or more of the compliant member(s) 106, is different from the thickness of the substrate contact area 104, or both. As one example, the unitary body can also be thinned in regions associated with the compliant members 106 to adjust bias forces associated with deformation of the compliant members 106.

The substrate contact area 104 is coupled to the compliant member(s) 106 along a perimeter of the lid 100. The die contact area 102 is coupled to the compliant member(s) 106 in an inner region of the lid 100. In FIG. 1A, the die contact area 102 and the substrate contact area 104 are illustrated as rectangular; however, in other examples, the die contact area 102, the substrate contact area 104, or both, have a different shape. To illustrate, the die contact area 102, the substrate contact area 104, or both, can have a different polygonal shape or a round (e.g., circular or oval) shape. The shape of the die contact area 102 and the substrate contact area 104 for a particular integrated device package 150 can be selected based on factors including the shape of the die 120 to be covered by the lid 100, whether other components in addition to the die 120 are to be covered by the lid 100 (and if so, the arrangement of such other components), the shape of the substrate 126 to which the lid 100 will be attached, surface constraints of the substrate 126 (e.g., locations of areas of the substrate 126 to which the substrate contact area 104 cannot be attached), etc.

Further, in FIG. 1A, the die contact area 102 and the substrate contact area 104 are illustrated as generally concentric (e.g., a center or centroid of the die contact area 102 is aligned with a center or centroid of the substrate contact area 104). In other examples, the center or centroid of the die contact area 102 may be offset from the center or centroid of the substrate contact area 104. For example, the die contact area 102 can be shifted to one side or the other along the Y and/or X-axes of FIG. 1A. When the die contact area 102 is shifted to one side, the compliant member(s) 106 along that side may be omitted or may have a different configuration than one or more others of the compliant members 106. For example, to accommodate shifting the die contact area 102 toward the right side (e.g., a positive X direction) in the orientation illustrated in FIG. 1A, the compliant member 106B along the right side may be omitted or may include fewer turns than the compliant member 106A along the left side. This difference in configuration of the compliant members 106 may cause the compliant members 106 to provide different bias forces, which may be useful for controlling particular warpage tendencies of the integrated device package 150.

While the lid 100 can be formed using additive processes (such as 3D printing), it may be more efficient to form the lid 100 using subtractive processes. For example, the lid 100 can be formed by stamping, cutting, etching, or otherwise removing portions of a sheet of material (typically a metal, such as copper) to define the opening(s) 108. To illustrate, a sheet of copper or another metal can be stamped to define the opening(s) 108 as well as to cut the lid 100 from a remaining portion of the sheet. In some examples, the stamping process can thin portions of the lid 100 at the same time that the opening(s) 108 are formed.

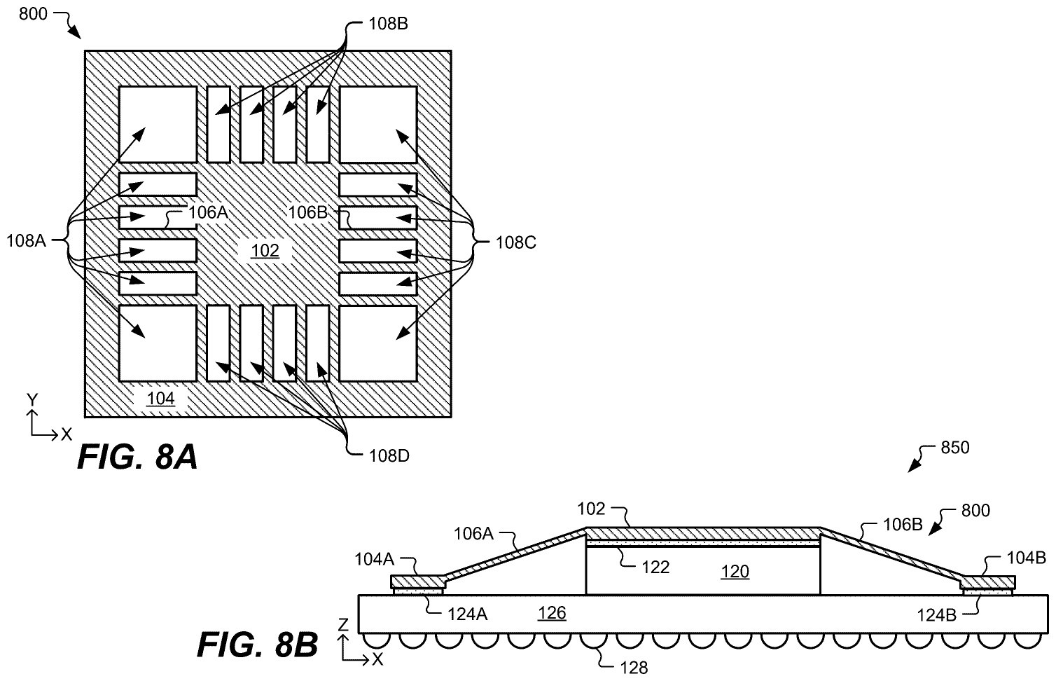

FIGS. 2-8A, 9-17A, 18A, 19A, and 20A illustrate schematic plan views of examples of lids for integrated device packages. FIGS. 8B, 17B, 18B, 19B, 20B, and 20C illustrate schematic cross-sectional views of integrated device packages that include the lids of FIGS. 8A, 17A, 18A, 19A, 20A, and 20A, respectively.

The various lids of FIGS. 2-20C highlight different lid configurations. Thus, each lid configuration represented in FIGS. 2-20C can be considered an example of the lid 100, and the various features, functions, and advantages described with reference to the lid 100 of FIGS. 1A and 1B also apply to the lids of FIGS. 2-20C. For example, each of the lids of FIGS. 2-20C includes a unitary body with the die contact area 102, the substrate contact area 104, and the compliant member(s) 106 defined by the opening(s) 108 between the die contact area 102 and the substrate contact area 104.

As explained above, the lid 200 of FIG. 2 includes examples of the compliant members 106 with fewer and wider turns than the compliant members 106 of the lid 100 of FIG. 1A. In FIG. 2, one of the compliant members 106 is coupled adjacent to each angle of the die contact area 102. For example, a compliant member 106A is coupled to the die contact area 102 adjacent to an angle 202 of the lid 200, a compliant member 106B is coupled to the die contact area 102 adjacent to an angle 206, a compliant member 106C is coupled to the die contact area 102 adjacent to an angle 208, and a compliant member 106D is coupled to the die contact area 102 adjacent to an angle 204. When compliant members 106 having the arrangement illustrated in FIG. 2 are flexed, the compliant members 106 exert a rotational force 210 on the die contact area 102 (and any underlying components to which the die contact area 102 is coupled, such as the die 120 or the TIM 122 of FIG. 1B). In some cases, the rotational force 210 can facilitate more intimate contact between the die contact area 102 and the TIM 122, between the TIM 122 and the die 120, or both, which can improve thermal performance of an integrated device package.

FIG. 3 illustrates an example of a lid 300 in which the compliant members 106 are arranged to generate a linear force 310 rather than the rotational force 210 of FIG. 2. In FIG. 3, the compliant member 106A and the compliant member 106C are coupled to the die contact area 102 adjacent to the angle 208 of the lid 200, and the compliant member 106B and the compliant member 106D are coupled to the die contact area 102 adjacent to the angle 204. When compliant members 106 having the arrangement illustrated in FIG. 3 are flexed, the compliant members 106 exert the linear force 310 on the die contact area 102 (and any underlying components to which the die contact area 102 is coupled).

The configuration illustrated in FIG. 2 may be preferred in some circumstances and the configuration illustrated in FIG. 3 may be preferred in other circumstances. For example, the configuration illustrated in FIG. 3 may be preferred when applying the rotational force 210 to components beneath the lid 200 would risk damaging the components or electrical connections therebetween. Conversely, the configuration illustrated in FIG. 2 may be preferred when the rotational force 210 tends to improve contact between the TIM 122 and the die 120 or the die contact area 102.

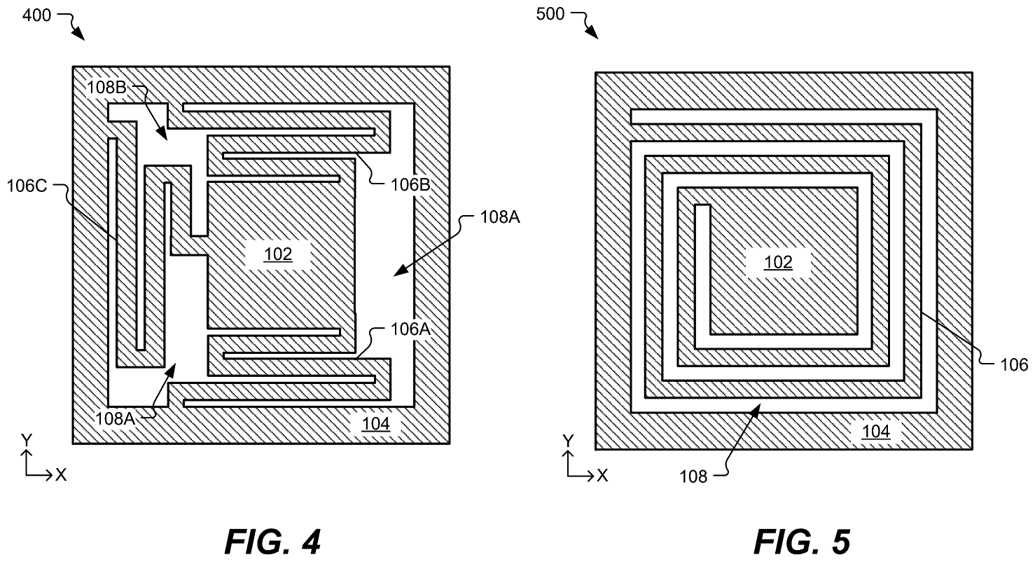

In contrast to the lids 100, 200, and 300 of FIGS. 1A-3, in FIG. 4, the die contact area 102 of a lid 400 is offset or shifted to one side (e.g., to the right along the X-axis in the orientation illustrated), and no compliant member is present on that side. For example, the lid 400 includes a compliant member 106A, and a compliant member 106B on opposite sides of the die contact area 102 from one another, and a compliant member 106C adjacent to each of the compliant members 106A and 106B. The compliant members 106A-106C are defined by openings 108A-108C in the unitary body of the lid 400. Although the lid 400 is illustrated as having compliant members 106 that follow meandering paths, lids in which the die contact area 102 is offset can include other types of compliant members, such as straight or looping compliant members as describe further below.

FIG. 5 illustrates an example of a lid 500 that includes a single compliant member 106. In FIG. 5, the compliant member 106 is defined by a single opening 108 in the unitary body of the lid 500. The number of turns of the compliant member 106 around the die contact area 102, the width of the compliant member 106, and the thickness of the compliant members 106 can be selected (e.g., tuned during fabrication or design) to provide particular bias forces when the lid 500 is attached to an integrated device package (e.g., the integrated device package 150).

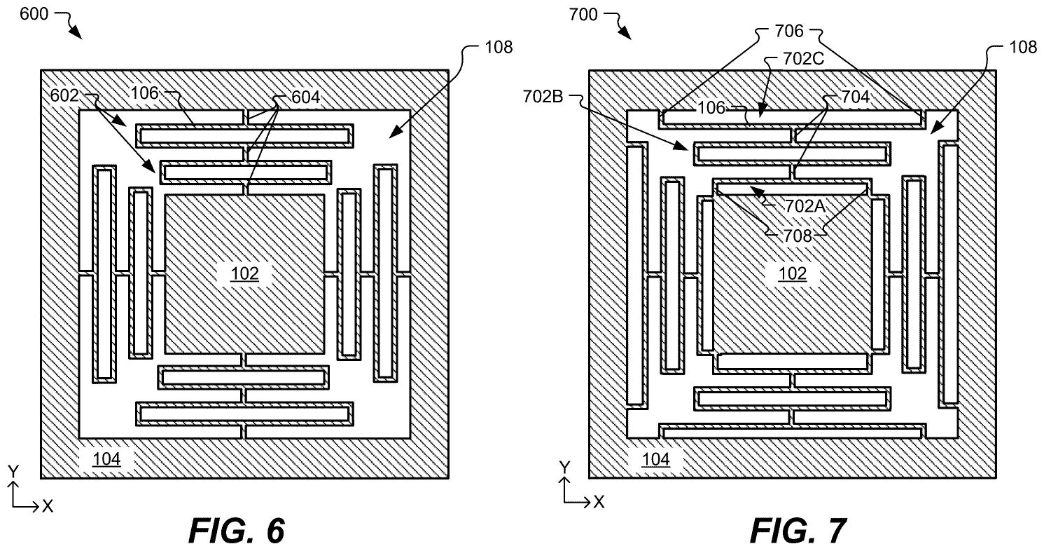

FIG. 6 illustrates an example of a lid 600 that includes multiple compliant members 106 that define looping paths on each side of the die contact area 102. For example, a representative compliant member 106 of the lid 600 includes one or more loops 602 and connectors 604 between adjacent ones of the loop(s) 602, between one of the loop(s) 602 and the die contact area 102, and between one of the loop(s) 602 and the substrate contact area 104.

The number of compliant members 106 on each side of the die contact area 102, the number of loops 602 per compliant member 106, the number of connectors 604, the locations of the connectors 604, the width of each portion of each of the compliant members 106, and the thickness of each portion of each of the compliant members 106 can be selected (e.g., tuned during fabrication or design) to provide particular bias forces when the lid 600 is attached to an integrated device package (e.g., the integrated device package 150).

FIG. 7 illustrates another example of a lid 700 that includes multiple compliant members 106 that define looping paths on each side of the die contact area 102. For example, a representative complaint 106 of the lid 700 includes one or more loops 702 and connectors 704 between adjacent ones of the loop(s) 702. In the example illustrated in FIG. 7, a loop 702A is broken to form connections 708 to the die contact area 102, or viewed another way, a side of the die contact area 102 forms one side of the loop 702A. Similarly, a loop 702C is broken to form connections 706 to the substrate contact area 104, or a side of the substrate contact area 104 forms one side of the loop 702C.

The number of compliant members 106 on each side of the die contact area 102, the number of loops 702 per compliant member 106, the number of the connectors 704, the locations of the connectors 704, the width of each portion of each of the compliant members 106, and the thickness of each portion of each of the compliant members 106 can be selected (e.g., tuned during fabrication or design) to provide particular bias forces when the lid 600 is attached to an integrated device package (e.g., the integrated device package 150).

FIGS. 8A and 8B illustrate an example of a lid 800 in which the compliant members 106 are substantially straight (rather than meandering, as in FIGS. 1A-5 or looping as in FIGS. 6 and 7). For example, a first arm (e.g., compliant member 106A) of a plurality of arms corresponding to the compliant members 106 defines a straight path between the die contact area 102 and the substrate contact area 104. Compliant members 106 that are substantially straight tend to be less flexible than compliant members 106 that meander or loop. Accordingly, the lid 800 may be used for integrated device packages 850 that require less flexible lids. Further, the bias force provided by the lid 800 can be tuned (during fabrication of the lid 800) by adjusting the width or thickness of one or more of the compliant members 106. For example, for a given displacement, wider compliant members 106 tend to exert a stronger bias force than narrower compliant members 106. Similarly, for the given displacement, thicker compliant members 106 tend to exert a stronger bias force than thinner compliant members 106.

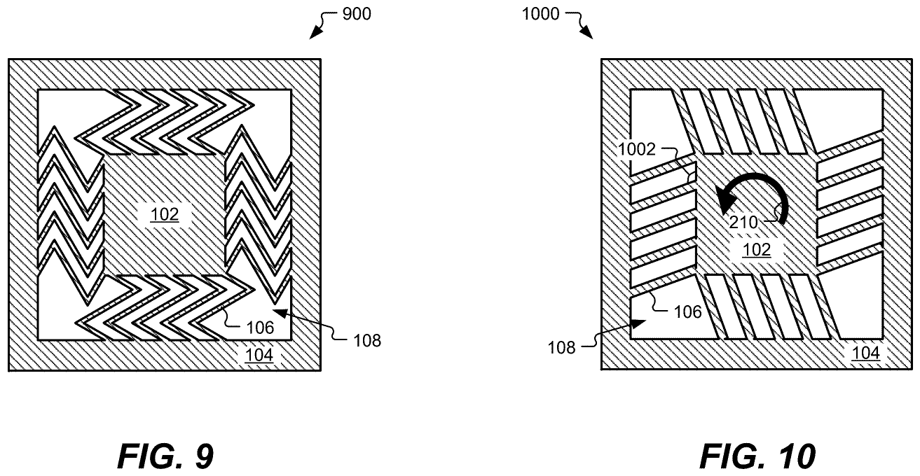

FIG. 9 illustrates an example of a lid 900 that includes multiple compliant members 106 that define meandering paths on each side of the die contact area 102. The number of compliant members 106 on each side of the die contact area 102, the number of turns or bends per compliant member 106, the width of each of the compliant members 106, and the thickness of each of the compliant members 106 can be selected (e.g., tuned during fabrication or design) to provide particular bias forces when the lid 900 is attached to an integrated device package (e.g., the integrated device package 150).

FIG. 10 illustrates an example of a lid 1000 that includes compliant members 106 that are substantially straight. In FIG. 10, each of the compliant members 106 is oriented to form an angle 1002 between the compliant members 106 and an outer edge of the die contact area 102. In FIG. 10, each of the compliant members 106 is oriented at about the same angle 1002 such that the compliant members 106 tend to generate the rotational force 210 when the lid 1000 is attached to an integrated device package (e.g., the integrated device package 150). In some examples, the compliant members 106 of the lid 1000 are rearranged to have different (e.g., opposing) angles to reduce or eliminate the rotational force 210. The number of compliant members 106 on each side of the die contact area 102, the width of each of the compliant members 106, and the thickness of each of the compliant members 106 can be selected (e.g., tuned during fabrication or design) to provide particular bias forces when the lid 1000 is attached to an integrated device package (e.g., the integrated device package 150).

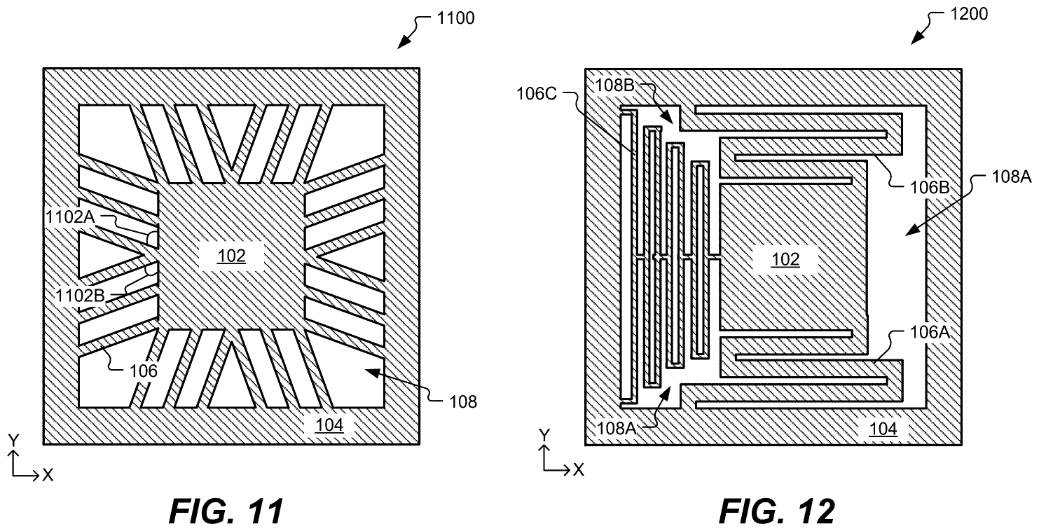

FIG. 11 illustrates another example of a lid 1100 that includes compliant members 106 that are substantially straight. In FIG. 11, the compliant members 106 on each side of the die contact area 102 are oriented to form opposing angles (e.g., angle 1102A and angle 1102B) between the compliant members 106 and an outer edge of the die contact area 102. The opposing angles 1102 of the lid 1100 tend to reduce or eliminate the rotational force 210 of the lid 1000 of FIG. 10. The number of compliant members 106 on each side of the die contact area 102, the width of each of the compliant members 106, and the thickness of each of the compliant members 106 can be selected (e.g., tuned during fabrication or design) to provide particular bias forces when the lid 1100 is attached to an integrated device package (e.g., the integrated device package 150).

FIG. 12 illustrates an example of a lid 1200 that includes different types of compliant members 106. For example, in FIG. 12, compliant members 106A, and 106B on opposite sides of the die contact area 102 from one another each have meandering paths, and a compliant member 106C on another side of the die contact area 102 includes loops. Further, in the example illustrated in FIG. 12, the die contact area 102 is offset to one side (e.g., to the right in the orientation illustrated), and no compliant member is disposed on that side of the die contact area 102.

In other examples, the lid 1200 can include other combinations of the compliant members 106. To illustrate, meandering compliant members can be used in combination with straight compliant members. Further, the number of compliant members 106 around the die contact area 102, which sides of the die contact area 102 are coupled to compliant members 106, locations of connections between the die contact area 102 and each compliant member 106, and the characteristics of each of the compliant members 106 can be selected (e.g., tuned during fabrication or design) to provide particular bias forces when the lid 1400 is attached to an integrated device package. The characteristics of the compliant members 106 can include, for example, the type (meandering, curving, looping, straight) of each compliant member 106 and the dimensions (thickness and width) of each portion of each compliant member. Additionally, the characteristics can include aspects that are specific to certain types of compliant members 106. To illustrate, meandering compliant members can be associated with a count of turns, and looping compliant members can be associated with a count of loops.

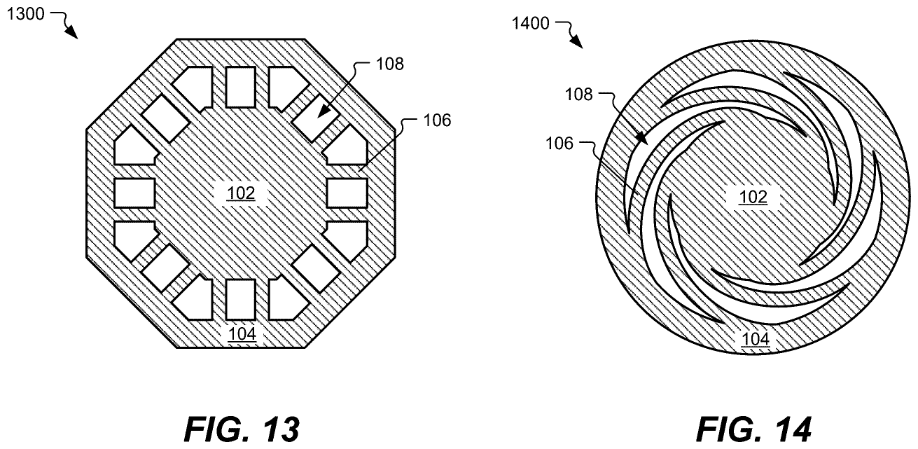

FIG. 13 illustrates an example of a lid 1300 in which the die contact area 102 and the substrate contact area 104 have non-rectangular polygonal shapes. In FIG. 13, the die contact area 102 and the substrate contact area 104 each have an octagonal shape. In other examples, the die contact area 102, the substrate contact area 104, or both, can have a different polygonal shape. In general, the die contact area 102, the substrate contact area 104, or both, can have any polygon shape including N sides joined at N angles, where N is an integer greater than 2. Further, in this general case, N×M compliant members 106 can be disposed on sides of the die contact area 102 between the die contact area 102 and the substrate contact area 104, where M is an integer greater than or equal to 1.

The number of sides (N) can be selected based on the layout and shape of one or more components (e.g., the die 120 or the substrate 126 of FIG. 1B) of an integrated device package (e.g., the integrated device package 150 of FIG. 1B). Further, the number (M) of compliant members 106 on each side of the die contact area 102, the width of each of the compliant members 106, and the thickness of each of the compliant members 106 can be selected (e.g., tuned during fabrication or design) to provide particular bias forces when the lid 1300 is attached to an integrated device package (e.g., the integrated device package 150).

In some embodiments, the compliant members 106 are attached to the die contact area 102 adjacent to each of the N angles. For example, FIGS. 2, 7, 8A, 9-11, and 13 illustrate examples of lids that include compliant members 106 attached to a die contact area 102 adjacent to each of the N angles. In other embodiments, the compliant members 106 are attached to the die contact area 102 adjacent to fewer than N of the N angles. For example, FIG. 3 illustrates an example of a lid 300 that includes compliant members 106 attached to a die contact area 102 adjacent to half of the N angles. FIGS. 4, 5, and 12 illustrate other examples of lids that include compliant member(s) 106 attached adjacent to fewer than the N angles of the die contact area 102. Further, FIG. 6 illustrates an example of a lid 600 in which the compliant members 106 are attached to the die contact area 102 at locations that are not adjacent to angles of the die contact area 102.

FIG. 14 illustrates an example of a lid 1400 in which the die contact area 102 and the substrate contact area 104 have non-polygonal shapes. In particular, in FIG. 14, the die contact area 102 and the substrate contact area 104 are each round (e.g., circular or oval). Additionally, in FIG. 14, the compliant members 106 are neither meandering nor straight. Rather, each compliant member 106 is curved. In other embodiments, straight, looping, or meandering compliant members 106 can be used with the die contact area 102 and the substrate contact area 104 that have non-polygonal shapes. The number of compliant members 106 around the die contact area 102, the width of each of the compliant members 106, and the thickness of each of the compliant members 106 can be selected (e.g., tuned during fabrication or design) to provide particular bias forces when the lid 1400 is attached to an integrated device package (e.g., the integrated device package 150).

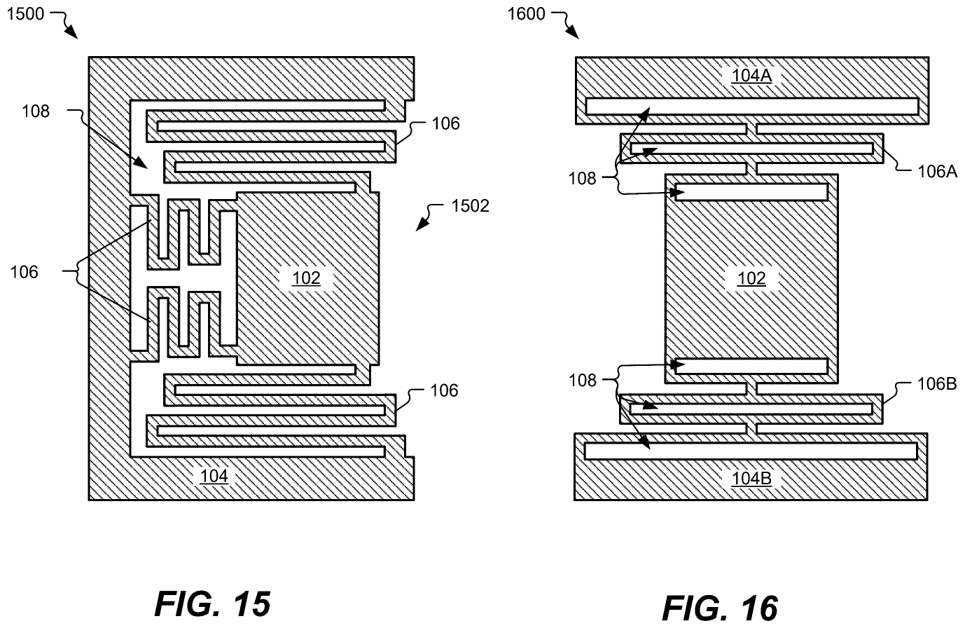

FIG. 15 illustrates an example of a lid 1500 in which the substrate contact area 104 does not fully surround the die contact area 102. For example, in FIG. 15, the substrate contact area 104 is open or discontinuous on a side 1502. In the example illustrated in FIG. 15, different numbers of compliant members 106 are present on different sides of the die contact area 102.

In other examples, the lid 1500 can include other combinations of the compliant members 106. To illustrate, the lid 1500 can include meandering compliant members on one or more sides of the die contact area 102 and straight or looping compliant members on one or more other sides of the die contact area 102. Further, the number of compliant members 106 around the die contact area 102, which sides of the die contact area 102 are coupled to compliant members 106, locations of connections between the die contact area 102 and each compliant member 106, and the characteristics of each of the compliant members 106 can be selected (e.g., tuned during fabrication or design) to provide particular bias forces when the lid 1500 is attached to an integrated device package. The characteristics of the compliant members 106 can include, for example, the type (meandering, curving, looping, straight) of each compliant member 106 and the dimensions (thickness and width) of each portion of each compliant member. Additionally, the characteristics can include aspects that are specific to certain types of compliant members 106. To illustrate, meandering compliant members can be associated with a count of turns, and looping compliant members can be associated with a count of loops.

FIG. 16 illustrates an example of a lid 1600 in which the substrate contact area 104 includes two or more disconnected portions. For example, in FIG. 16, the substrate contact area 104 includes a first portion (e.g., substrate contact area 104A) and a second portion (e.g., substrate contact area 104B). In other examples, the lid 1600 includes more than two disconnected portions.

In other examples, the lid 1600 can include other combinations of the compliant members 106. For example, the number of compliant members 106 around the die contact area 102, which sides of the die contact area 102 are coupled to compliant members 106, locations of connections between the die contact area 102 and each compliant member 106, and the characteristics of each of the compliant members 106 can be selected (e.g., tuned during fabrication or design) to provide particular bias forces when the lid 1600 is attached to an integrated device package. The characteristics of the compliant members 106 can include, for example, the type (meandering, curving, looping, straight) of each compliant member 106 and the dimensions (thickness and width) of each portion of each compliant member. Additionally, the characteristics can include aspects that are specific to certain types of compliant members 106. To illustrate, meandering compliant members can be associated with a count of turns, and looping compliant members can be associated with a count of loops.

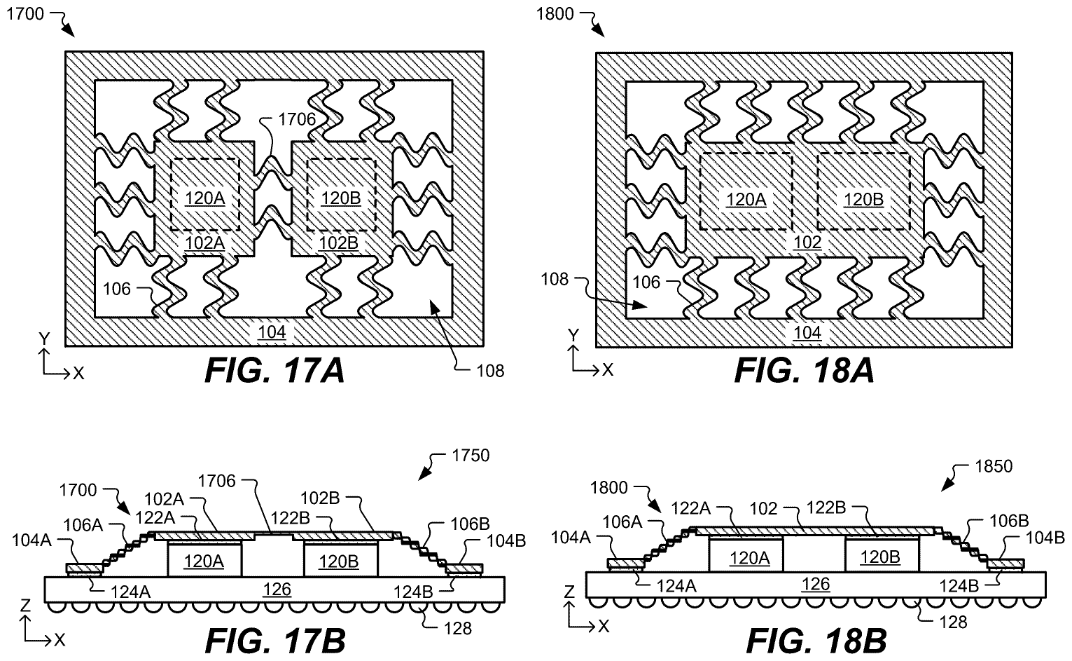

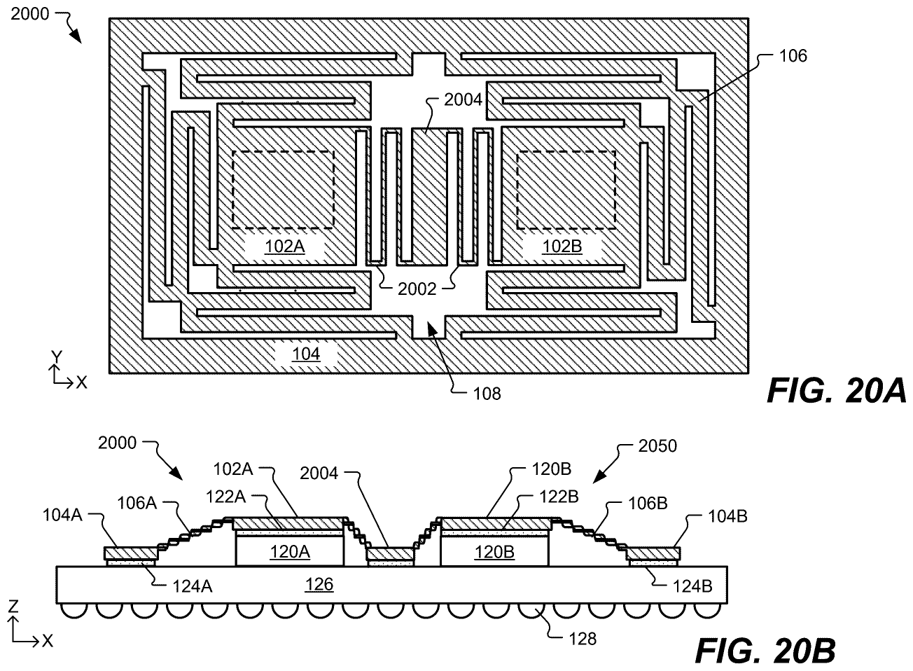

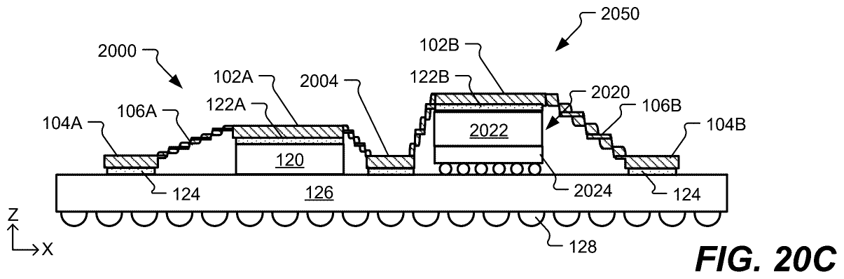

FIGS. 17A, 18A, 19A, and 20A illustrate schematic plan views of examples of lids for integrated device packages that are configured to cover multiple components. FIGS. 17B, 18B, 19B, and 20B illustrate schematic cross-sectional views of examples of integrated device packages that include the lids of FIGS. 17A, 18A, 19A, and 20A, respectively. FIG. 20C illustrates a schematic cross-sectional view of another example of an integrated device package that includes the lid of FIG. 20A.

In FIGS. 17A and 17B, a lid 1700 includes multiple die contact areas 102 (including die contact area 102A, and die contact area 102B), and each die contact area 102 is disposed over a corresponding die 120. For example, in FIG. 17B, the die 120A is coupled to (e.g., in contact with) TIM 122A, and the TIM 122A is coupled to (e.g., in contact with) the die contact area 102A. Likewise, the die 120B is coupled to (e.g., in contact with) TIM 122B, and the TIM 122B is coupled to (e.g., in contact with) the die contact area 102B.

The compliant members 106 are disposed between each of the die contact areas 102 and the substrate contact area 104. Additionally, compliant members 1706 can be disposed between the die contact areas 102. Optionally, the compliant members 1706 between the die contact areas 102 can be omitted or can have a different configuration than the other compliant members 106 of the lid 1700. For example, the compliant members 106 can include meandering compliant members, and the compliant members 1706 can include straight, curved, or looping compliant members. In other examples, other combinations of compliant members 106, 1706 can be used.

FIGS. 17A and 17B illustrate an example in which the lid 1700 is associated with two dies 120. In other examples, the lid 1700 can be used for one die 120 and another type of component (e.g., a passive component). Further, in some examples, the lid 1700 can include more than two die contact areas 102, in which case the lid 1700 can be used to cover more than two dies 120 and/or other components of an integrated device package 1750.

In FIGS. 17A and 17B, the compliant members 106 and 1706 are illustrated as having meandering paths. In other examples, the compliant members 106, the compliant members 1706, or both, can have straight paths, curved paths, or looping paths. Further, the number of compliant members 106, 1706 on each side of each of the die contact areas 102; the width of each of the compliant members 106, 1706; and the thickness of each of the compliant members 106, 1706 can be selected (e.g., tuned during fabrication or design) to provide particular bias forces when the lid 1700 is attached to the integrated device package 1750.

In FIGS. 18A and 18B, a lid 1800 includes a single die contact area 102 that is configured to cover multiple components (e.g., dies 120A and 120B) of an integrated device package 1850. For example, in FIG. 18B, the die 120A is coupled to (e.g., in contact with) the TIM 122A, and the TIM 122A is coupled to (e.g., in contact with) the die contact area 102. Likewise, the die 120B is coupled to (e.g., in contact with) the TIM 122B, and the TIM 122B is coupled to (e.g., in contact with) the die contact area 102. The compliant members 106 are disposed between the die contact area 102 and the substrate contact area 104.

FIGS. 18A and 18B illustrate an example in which the lid 1800 is associated with two dies 120. In other examples, the lid 1800 can be used for one die 120 and another type of component (e.g., a passive component). Further, in some examples, the lid 1800 can be configured for use with more than two dies 120 and/or other types of components.

In FIGS. 18A and 18B, the compliant members 106 are illustrated as having meandering paths. In other examples, the compliant members 106 can have straight paths, curved paths, or looping paths. Further, the number of compliant members 106 on each side of the die contact area 102, the width of each of the compliant members 106, and the thickness of each of the compliant members 106 can be selected (e.g., tuned during fabrication or design) to provide particular bias forces when the lid 1800 is attached to the integrated device package 1850.

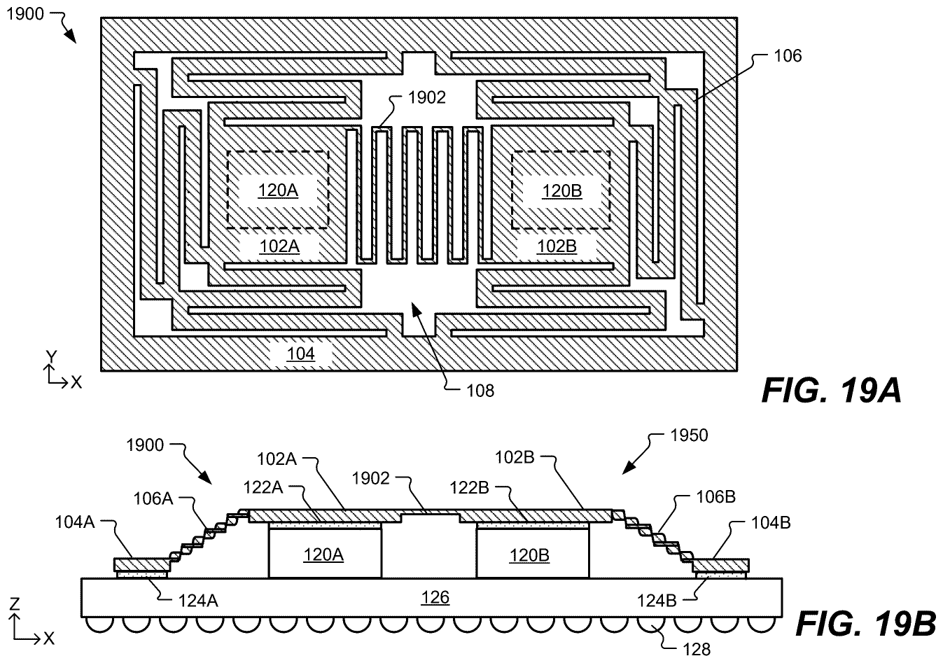

FIGS. 19A and 19B illustrate an example in which the lid 1900 includes two die contact areas 102 (e.g., die contact areas 102A and 102B). For example, the lid 1900 can be used for two dies (e.g., dies 120A and 120B) or for one die 120 and another type of component (e.g., a passive component).

In FIGS. 19A and 19B, each of the die contact areas 102 is coupled to a set of the compliant members 106. Additionally, one or more compliant members 1902 connect the die contact areas 102 to one another. In the example of FIGS. 19A and 19B, the compliant members 1902 between the die contact areas 102 have a different configuration than the compliant members 106 between the substrate contact area and each of the die contact areas 102. In other examples, the compliant members 106, the compliant members 1902, or both, can have straight paths, curved paths, or looping paths. Further, the number of compliant members 106, 1902 on each side of each of the die contact areas 102, the configuration of the contact members 106, 1902, or both, can be selected (e.g., tuned during fabrication or design) to provide particular bias forces when the lid 1900 is attached to the integrated device package 1950.

FIGS. 20A, 20B, and 20C illustrate examples in which a lid 2000 includes two die contact areas 102 (e.g., die contact areas 102A and 102B) and two substrate contact areas, including the substrate contact area 104 and a substrate contact area 2004 disposed between the die contact areas 102. The lid 2000 can be used with two dies or with one die 120 and another type of component (e.g., a passive component). For example, in FIG. 20B, the lid 2000 is used with two dies, including a die 120A and a die 120B. Although FIG. 20B illustrates the die 120A and the die 120B as similar in shape and size (e.g., footprint and thickness), in other examples, the dies 120 can have different shapes and/or different sizes than one another. As another example, in FIG. 20C, the lid 2000 is used with a die 120 and a packaged integrated circuit device 2020.

Each of the die contact areas 102 of the lid 2000 is coupled to a set of the compliant members 106 that couple the die contact area 102 to the substrate contact area. Additionally, the substrate contact area 2004 is coupled to each of the die contact areas 102 by compliant members 2002. In the example of FIG. 20A, the compliant members 2002 coupled to the substrate contact area 2004 have a different configuration than the compliant members 106 coupled to the substrate contact area 104. In other examples, the compliant members 106, the compliant members 2002, or both, can have straight paths, curved paths, or looping paths. Further, the number of compliant members 106, 2002 coupled to the substrate contact area 104 and the substrate contact area 2004 can be selected (e.g., tuned during fabrication or design) to provide particular bias forces when the lid 2000 is attached to the integrated device package 2050.

In some embodiments, the lid 2000 can include more than two die contact areas, more than two substrate contact areas, or both. To illustrate, the lid 2000 can include three die contact areas (arranged in a line or in a triangle) and a substrate contact area can be disposed between any two of the die contact areas or between each adjacent pair of the die contact areas.

FIG. 20C illustrates use of a lid (e.g., the lid 2000) with different types of components (e.g., the die 120 and the packaged integrated circuit device 2020). In this example, the packaged integrated circuit device 2020 includes a die 2022 coupled to a substrate 2024, resulting in a taller profile than the die 120. The compliant members 106, 2002 of the lid 2000 flex to accommodate the different profiles without requiring use of a lid that is specifically formed to accommodate multiple profiles.

### Exemplary Sequence for Fabricating a Lidded Integrated Device Package

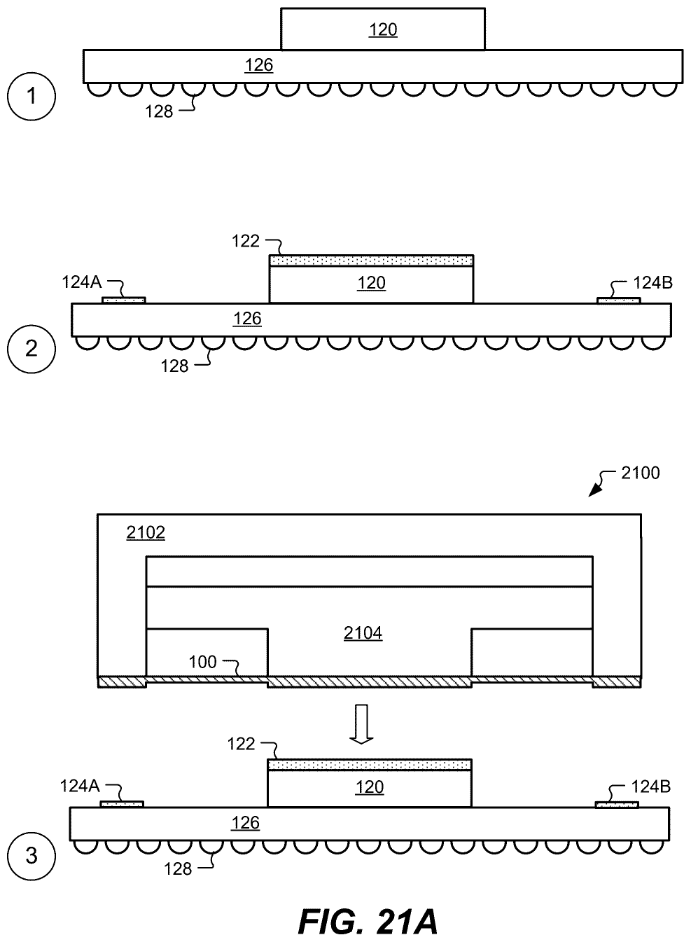

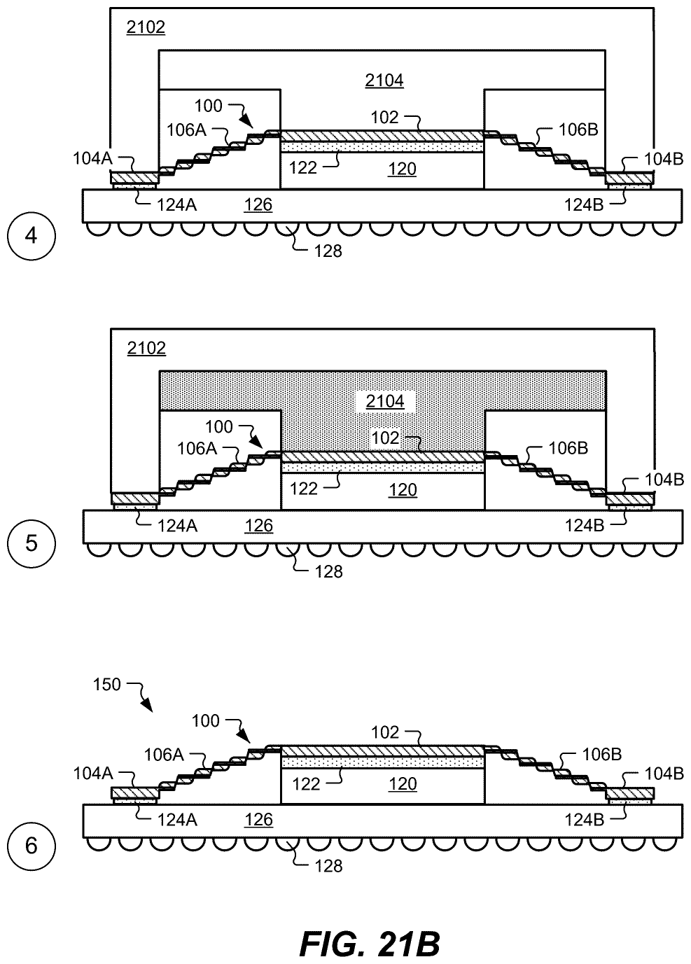

FIGS. 21A and 21B illustrate an exemplary sequence for fabricating or providing an integrated device package that includes a lid, such as any of the lids described with reference to FIGS. 1-20C. In some implementations, the sequence of FIGS. 21A-C may be used to provide (e.g., during fabrication of) one or more of the devices 150 or 180 of FIGS. 1B-1D, the device 850 of FIG. 8B, the device 1750 of FIG. 17B, the device 1850 of FIG. 18B, the device 1950 of FIG. 19B, or the device 2050 of FIG. 20B or 20C, or any of the variants described therewith.

It should be noted that the sequence of FIGS. 21A and 21B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 21A and 21B.

Stage 1 of FIG. 21A illustrates a state after a die 120 is coupled to a substrate 126. For example, the die 120 can be coupled to the substrate 126 using flip-chip die attach operations, such as solder reflow or thermocompression bonding. The substrate 126 includes conductors separated from one another by dielectric to form conductive paths to enable interconnection of the die 120 with other components. For example, some of the conductive paths of the substrate 126 can form off-package contacts, which are coupled to solder balls of a ball-grid array 128 in the example illustrated in FIG. 21A.

Stage 2 illustrates a state after the TIM 122 is applied to the die 120 and a bond material 124 is applied to a portion of the substrate 126. For example, the TIM 122, the bond material 124, or both, can be applied using processes such as dispensing, printing, extrusion, spraying, or painting. Further, although FIG. 21A illustrates the TIM 122 applied to the die 120 and the bond material 124 applied to the substrate 126, in other examples, the TIM 122, the bond material 124, or both, can be applied to a lid (e.g., the lid 100 of Stage 3).

Stage 3 illustrates a state after the lid 100 is coupled to an assembly device 2100 to facilitate coupling of the lid 100 to the die 120 and the substrate 126. For example, the assembly device 2100 can include vacuum ports that use vacuum to pick up the lid 100. As explained above, the lids 200, 300, 400, 500, 600, 700, 800, 900, 1000, 1100, 1200, 1300, 1400, 1500, 1600, 1700, 1800, 1900, and 2000 are examples of the lid 100; thus, for simplicity, FIGS. 21A and 21B illustrate the lid 100. It is understood that the lid 100 of FIGS. 21A and 21B can include any of the lids 200, 300, 400, 500, 600, 700, 800, 900, 1000, 1100, 1200, 1300, 1400, 1500, 1600, 1700, 1800, 1900, 2000, or any of the various additional configurations described above.

In the example illustrated in FIGS. 21A and 21B, the assembly device 2100 includes a frame 2102 and a head 2104 that are moveable with respect to one another. To illustrate, at Stage 3 of FIG. 21A, bottoms of the frame 2102 and the head 2104 are substantially aligned to facilitate picking up the lid 100. However, at Stage 4 of FIG. 21B, the bottom of the head 2104 is recessed relative to the bottom of the frame 2102.

Stage 4 of FIG. 21B illustrates a state after the die contact area 102 of the lid 100 contacts the TIM 122 arresting motion of the head 2104, and the frame 2102 slides further downward to contact the substrate contact area 104 of the lid 100 to the bond material 124. Motion of the frame 2102 relate to the head 2104 flexes the compliant members 106 of the lid 100.

Stage 5 illustrates an optional state in which a portion of the assembly device 2100 is heated to complete attachment of the lid 100 to the substrate 126 and/or the die 120. For example, in FIG. 21B, the head 2104 is heated (as illustrated by the dotted fill of the head 2104 at Stage 5) to improve a bond between the TIM 122 and the lid 100. In other examples, the frame 2102 can be heated to form or to improve a bond between the bond material 124 and the substrate contact area 104.

Stage 6 illustrates a state after the lid 100 is coupled to the die 120 and the substrate 126 to form an integrated device package 150. In some examples, formation of the integrated device package 150 is complete at Stage 6. In other examples, formation of the integrated device package 150 can include further operations, such as application of an underfill material between the die 120 and the substrate 126 or application of a mold compound to at least partially encapsulate the die 120, the substrate 126, and the lid 100. In some implementations, the integrated device package 150 can be assembled with one or more other components (e.g., using a PCB) to form a device, such as the device 180 of any of FIGS. 1B-1D.

Although certain Stages are illustrated in FIGS. 21A and 21B in forming the integrated device package 150, other processes can be included in the fabrication of the integrated device package 150 without departing from the scope of the subject disclosure.

### Exemplary Flow Diagram of a Method for Fabricating an Integrated Device Package Including a Compliant Lid

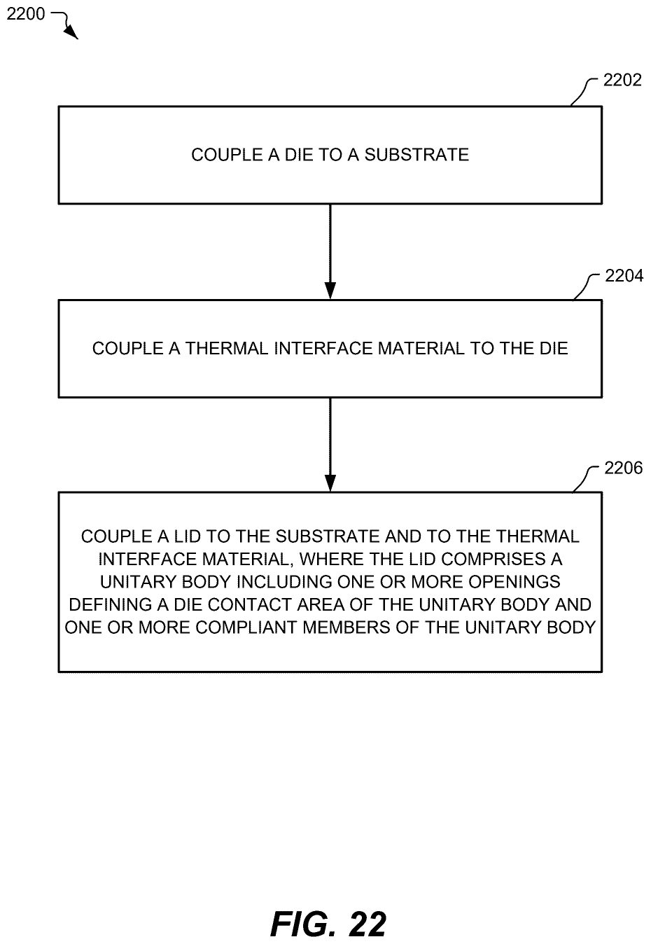

In some implementations, fabricating an integrated device package including a compliant lid includes several processes. FIG. 22 illustrates an exemplary flow diagram of a method 2200 of fabricating an illustrative integrated device package that includes a compliant lid. In a particular aspect, one or more operations of the method 2200 are initiated, performed, or controlled by one or more processors of a fabrication system. In some implementations, operations of the method 2200 may be stored as instructions by a non-transitory computer-readable storage medium, and the instructions may be executable by at least one processor to cause the at least one processor to initiate, perform, or control operations of the method 2200. In some implementations, the method 2200 of FIG. 22 may be used to provide or fabricate any of the integrated device packages of FIGS. 1B-1D, 8B, 17B, 18B, 19B, 20B, 20C, or 21B or other integrated device packages that include a compliant lid, such as any of the lids of FIGS. 1A-20B.

It should be noted that the method 2200 of FIG. 22 may combine one or more processes in order to simplify and/or clarify the method for providing or fabricating an integrated device package. In some implementations, the order of the processes may be changed or modified.

The method 2200 includes, at block 2202, coupling a die to a substrate. For example, the die can include or correspond to any of the dies 120 of FIGS. 1B-1D, 8B, 17B, 18B, 19B, 20B, 20C, or 21B, and the substrate can include or correspond to any of the substrates 126 of 1B-1D, 8B, 17B, 18B, 19B, 20B, 20C, 21A, or 21B. In some embodiments, another component (e.g., a passive component or a packaged integrated circuit device, such as the packaged integrated circuit device 2020 of FIG. 20C) or another die can also be coupled to the substrate at block 2202. Coupling the die to the substrate can include forming electrical connections between circuitry of the die and conductors of the substrate. For example, the die can include a flip-chip die, which can be coupled to the substrate using operations should as solder reflow or pad-to-pad bonding.

The method 2200 also includes, at block 2204, coupling a thermal interface material to the die. For example, the thermal interface material can include or correspond to the TIM 122 of any of 1B-1D, 8B, 17B, 18B, 19B, 20B, 20C, 21A, or 21B. The TIM can be coupled to the die as a paste, a gel, or a liquid using deposition techniques, such as printing, extrusion, or dispensing. Alternatively, the TIM can be applied to the substrate or to the substrate contact area of the lid as a film, e.g., using lamination techniques.

The method 2200 further includes, at block 2206, coupling a lid to the substrate and to the thermal interface material. The lid includes a unitary body including one or more openings defining a die contact area of the unitary body and one or more compliant members of the unitary body. For example, the lid can correspond to or include any of the lids of FIGS. 1A-20B.

The lid can be coupled to the substrate using a bond material 124, such as adhesive or solder. The adhesive can be applied to the substrate or to the substrate contact area of the lid as a paste, a gel, or a liquid using deposition techniques, such as printing, extrusion, or dispensing. Alternatively, the adhesive can be applied to the substrate or to the substrate contact area of the lid as a film, e.g., using lamination techniques. In other examples, the lid can be coupled to the substrate using other assembly techniques, such as plated-through hole assembly techniques.

In some embodiments, the method 2200 can also include forming the lid. For example, forming the lid can include forming one or more openings in a sheet of material. In this example, the opening(s) define different regions of the unitary body corresponding to the die contact area, the substrate contact area, and the compliant member(s). The compliant member(s) include arm(s) of the unitary body extending from multiple sides of the die contact area. The arm(s) can define straight paths, looping paths, meandering paths, or curved paths. The opening(s) can be formed using subtractive processes, such as machining, cutting, stamping, or etching.

In some embodiments, forming the lid can also include reducing a thickness of at least a portion of one or more of the compliant member(s). In such embodiments, a thickness of the die contact area is different from a thickness of the compliant member(s). The thickness of at least the portion of the one or more of the compliant member(s) can be reduced using subtractive processes, such as machining, cutting, stamping, or etching. For example, in some cases, a single stamping operation can form the opening(s) and reduce the thickness of one or more of the compliant member(s).

In some embodiments, the method 2200 can also include applying a mold compound to at least partially encapsulate the die. The mold compound can be applied before the lid or after the lid (e.g., through one or more openings of the lid). In some cases, a portion of the mold compound can be applied and cured before the lid is coupled to the substrate, and additional mold compound can be applied after the lid is coupled to the substrate.

In some embodiments, the method 2200 can also include electrically coupling the substrate to a printed circuit board. For example, the printed circuit board can include the PCB 130 of any of FIGS. 1B-1D.

### Exemplary Electronic Devices

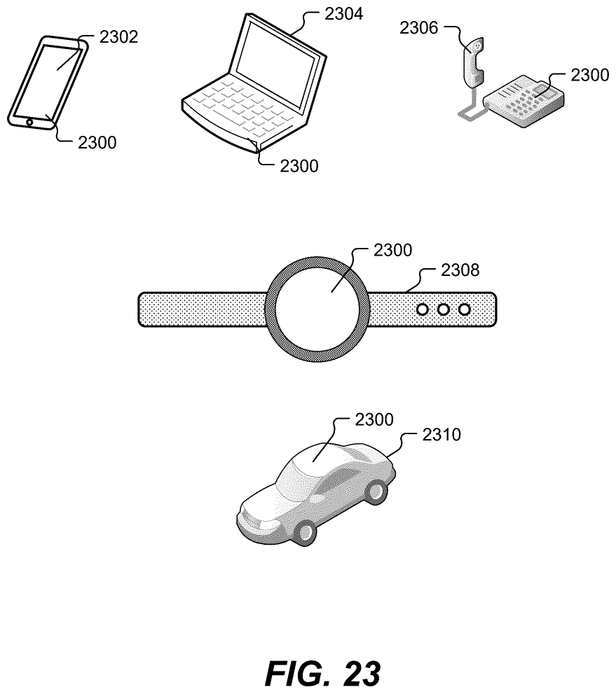

FIG. 23 illustrates various electronic devices that may include or be integrated with an integrated device package that includes any of the lids disclosed herein. For example, a mobile phone device 2302, a laptop computer device 2304, a fixed location terminal device 2306 (e.g., a server or server rack), a wearable device 2308, or a vehicle 2310 (e.g., an automobile or an aerial device) may include a device 2300. The device 2300 can include, for example, any of the devices 180 of FIGS. 1B-1D, the integrated device packages 150 of FIGS. 1B-1D, the integrated device package 850 of FIG. 8B, the integrated device package 1750 of FIG. 17B, the integrated device package 1850 of FIG. 18B, the integrated device package 1950 of FIG. 19B, the integrated device package 2050 of FIG. 20B, the integrated device package 2050 of FIG. 20C, or another integrated device package that includes any of the lids of FIGS. 1A-20B. The devices 2302, 2304, 2306 and 2308 and the vehicle 2310 illustrated in 23 FIG. 23 are merely exemplary. Other electronic devices may also feature the device 2300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-23 may be rearranged and/or combined into a single component, process, feature or function or embodied in several components, processes, or functions. Additional elements, components, processes, and/or functions may also be added without departing from the disclosure. It should also be noted FIGS. 1A-23 and its corresponding description in the present disclosure is not limited to dies and/or ICs. In some implementations, FIG. 1A-23 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, an integrated device package includes a substrate; a die coupled to the substrate; a thermal interface material coupled to the die; and a lid coupled to the substrate and to the thermal interface material. The lid includes a unitary body including one or more openings that define a die contact area of the unitary body and one or more compliant members of the unitary body.

Example 2 includes the integrated device package of Example 1, wherein the unitary body includes a substrate contact area coupled to the one or more compliant members along a perimeter of the lid, wherein the lid is coupled to the substrate via bond material between the substrate contact area and the substrate.

Example 3 includes the integrated device package of Example 1 or Example 2, wherein the one or more compliant members include one or more arms of the unitary body that extend from one or more sides of the die contact area.

Example 4 includes the integrated device package of Example 3, wherein a first arm of the one or more arms defines a meandering path between the die contact area and a substrate contact area of the unitary body.

Example 5 includes the integrated device package of Example 3, wherein a first arm of the one or more arms defines a straight path between the die contact area and a substrate contact area of the unitary body.

Example 6 includes the integrated device package of any of Examples 1 to 5, wherein a thickness of the die contact area is substantially equal to a thickness of the one or more compliant members.

Example 7 includes the integrated device package of any of Examples 1 to 5, wherein a thickness of the die contact area is different from a thickness of the one or more compliant members.

Example 8 includes the integrated device package of any of Examples 1 to 7, wherein the one or more compliant members are configured to apply a rotational force to the die contact area.

Example 9 includes the integrated device package of any of Examples 1 to 8, wherein the die contact area has a polygon shape including N sides joined at N angles, where N is an integer greater than 2, and wherein the one or more compliant members include N×M compliant members where M is an integer greater than or equal to 1.

Example 10 includes the integrated device package of Example 9, wherein the one or more compliant members are attached to the die contact area adjacent to each of the N angles.

Example 11 includes the integrated device package of Example 9, wherein the one or more compliant members are attached to the die contact area adjacent to half of the N angles.

Example 12 includes the integrated device package of any of Examples 9 to 11, wherein one or more first compliant members attached to a first side of the die contact area have a first configuration and one or more second compliant members attached to a second side of the die contact area have a second configuration different from the first configuration.

Example 13 includes the integrated device package of any of Examples 1 to 12, further includes one or more second dies coupled to the substrate; and additional thermal interface material coupled to each of the one or more second dies, wherein the lid is coupled to the additional thermal interface material.

Example 14 includes the integrated device package of any of Examples 1 to 13, wherein the substrate is a package substrate, and the integrated device package further includes a printed circuit board electrically coupled to the package substrate.

Example 15 includes the integrated device package of any of Examples 1 to 14, wherein the one or more openings are spaced and sized to provide target bias forces between the thermal interface material and the substrate based on material properties of the unitary body.

Example 16 includes the integrated device package of any of Examples 1 to 15 and further includes a ball grid array coupled to the substrate.

According to Example 17, a device includes a printed circuit board and an integrated device package electrically connected to the printed circuit board. The integrated device package includes a substrate; a die coupled to the substrate; a thermal interface material coupled to the die; and a lid coupled to the substrate and to the thermal interface material. The lid includes a unitary body including one or more openings that define a die contact area of the unitary body and one or more compliant members of the unitary body.

Example 18 includes the device of Example 17 and further including an electromagnetic shield lid coupled to the printed circuit board over the integrated device package.

Example 19 includes the device of Example 17 or Example 18, wherein the unitary body includes a substrate contact area coupled to the one or more compliant members along a perimeter of the lid, wherein the lid is coupled to the substrate via a bond material between the substrate contact area and the substrate.

Example 20 includes the device of Example 17 or Example 19, wherein the one or more compliant members include one or more arms of the unitary body that extend from one or more sides of the die contact area.

Example 21 includes the device of Example 20, wherein a first arm of the one or more arms defines a meandering path between the die contact area and a substrate contact area of the unitary body.

Example 22 includes the device of Example 20, wherein a first arm of the one or more arms defines a straight path between the die contact area and a substrate contact area of the unitary body.

Example 23 includes the device of any of Examples 17 to 22, wherein a thickness of the die contact area is substantially equal to a thickness of the one or more compliant members.

Example 24 includes the device of any of Examples 17 to 22, wherein a thickness of the die contact area is different from a thickness of the one or more compliant members.

Example 25 includes the device of any of Examples 17 to 24, wherein the one or more compliant members are configured to apply a rotational force to the die contact area.

Example 26 includes the device of any of Examples 17 to 25, wherein the die contact area has a polygon shape including N sides joined at N angles, where N is an integer greater than 2, and wherein the one or more compliant members include N×M compliant members where M is an integer greater than or equal to 1.

Example 27 includes the device of Example 26, wherein the one or more compliant members are attached to the die contact area adjacent to each of the N angles.

Example 28 includes the device of Example 26, wherein the one or more compliant members are attached to the die contact area adjacent to half of the N angles.

Example 29 includes the device of any of Examples 26 to 28, wherein one or more first compliant members attached to a first side of the die contact area have a first configuration and one or more second compliant members attached to a second side of the die contact area have a second configuration different from the first configuration.

Example 30 includes the device of any of Examples 17 to 29, further includes one or more second dies coupled to the substrate; and additional thermal interface material coupled to each of the one or more second dies, wherein the lid is coupled to the additional thermal interface material.

Example 31 includes the device of any of Examples 17 to 30, wherein the one or more openings are spaced and sized to provide target bias forces between the thermal interface material and the substrate based on material properties of the unitary body.

Example 32 includes the device of any of Examples 17 to 31 and further includes a ball grid array coupled to the substrate.

According to Example 33, a method of fabricating an integrated device package includes coupling a die to a substrate and coupling a thermal interface material to the die. The method also includes coupling a lid to the substrate and to the thermal interface material. The lid includes a unitary body including one or more openings defining a die contact area of the unitary body and one or more compliant members of the unitary body.

Example 34 includes the method of Example 33 and further includes forming openings in a sheet of material to form the lid.

Example 35 includes the method of Example 33 or Example 34, wherein the one or more compliant members include one or more arms of the unitary body extending from one or more sides of the die contact area.

Example 36 includes the method of Example 35, wherein a first arm of the one or more arms defines a meandering path between the die contact area and a substrate contact area of the unitary body.

Example 37 includes the method of Example 35, wherein a first arm of the one or more arms defines a straight path between the die contact area and a substrate contact area of the unitary body.

Example 38 includes the method of any of Examples 33 to 37, wherein a thickness of the die contact area is substantially equal to a thickness of the one or more compliant members.

Example 39 includes the method of any of Examples 33 to 37, wherein a thickness of the die contact area is different from a thickness of the one or more compliant members.

Example 40 includes the method of any of Examples 33 to 39, wherein the one or more compliant members are configured to apply a rotational force to the die contact area.

Example 41 includes the method of any of Examples 33 to 40, wherein the die contact area has a polygon shape including N sides joined at N angles, where N is an integer greater than 2, and wherein the one or more compliant members include N×M compliant members where M is an integer greater than or equal to 1.

Example 42 includes the method of Example 41, wherein the one or more compliant members are attached to the die contact area adjacent to each of the N angles.

Example 43 includes the method of Example 41, wherein the one or more compliant members are attached to the die contact area adjacent to half of the N angles.

Example 44 includes the method of any of Examples 33 to 43, wherein one or more first compliant members attached to a first side of the die contact area have a first configuration and one or more second compliant members attached to a second side of the die contact area have a second configuration different from the first configuration.

Example 45 includes the method of any of Examples 33 to 44 and further includes electrically connecting the substrate to a printed circuit board.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device package comprising:
a substrate;
a die coupled to the substrate;
a thermal interface material coupled to the die; and
a lid coupled to the substrate and to the thermal interface material, the lid comprising a unitary body including one or more openings that define a die contact area of the unitary body and one or more compliant members of the unitary body.

2. The integrated device package of claim 1, wherein the unitary body includes a substrate contact area coupled to the one or more compliant members along a perimeter of the lid, wherein the substrate contact area is coupled to the substrate.

3. The integrated device package of claim 1, wherein the one or more compliant members comprise one or more arms of the unitary body that extend from one or more sides of the die contact area.

4. The integrated device package of claim 1, wherein the one or more compliant members are configured to apply a rotational force to the die contact area.

5. The integrated device package of claim 1, wherein the die contact area has a polygon shape including N sides joined at N angles, where N is an integer greater than 2, and wherein the one or more compliant members include N×M compliant members where M is an integer greater than or equal to 1.

6. The integrated device package of claim 5, wherein the one or more compliant members are attached to the die contact area adjacent to each of the N angles.

7. The integrated device package of claim 5, wherein the one or more compliant members are attached to the die contact area adjacent to half of the N angles.

8. The integrated device package of claim 5, wherein one or more first compliant members attached to a first side of the die contact area have a first configuration and one or more second compliant members attached to a second side of the die contact area have a second configuration different from the first configuration.

9. The integrated device package of claim 1, further comprising:
one or more second dies coupled to the substrate; and
additional thermal interface material coupled to each of the one or more second dies, wherein the lid is coupled to the additional thermal interface material.

10. The integrated device package of claim 1, wherein the substrate is a package substrate, and further comprising a printed circuit board electrically connected to the package substrate.

11. The integrated device package of claim 1, wherein the one or more openings are spaced and sized to provide target bias forces between the thermal interface material and the substrate based on material properties of the unitary body.

12. The integrated device package of claim 1, further comprising a ball grid array coupled to the substrate.

13. A device comprising:
a printed circuit board; and
an integrated device package electrically connected to the printed circuit board, the integrated device package comprising:
a substrate;
a die coupled to the substrate;
a thermal interface material coupled to the die; and
a lid coupled to the substrate and to the thermal interface material, the lid comprising a unitary body including one or more openings that define a die contact area of the unitary body and one or more compliant members of the unitary body.

14. The device of claim 13, further comprising an electromagnetic shield lid coupled to the printed circuit board over the integrated device package.

15. The device of claim 13, wherein the unitary body includes a substrate contact area coupled to the one or more compliant members along a perimeter of the lid, wherein the lid is coupled to the substrate via bond material between the substrate contact area and the substrate.

16. The device of claim 13, wherein the one or more compliant members comprise one or more arms of the unitary body that extend from one or more sides of the die contact area.

17. The device of claim 13, wherein the one or more compliant members are configured to apply a rotational force to the die contact area.

18. The device of claim 13, wherein the one or more openings are spaced and sized to provide target bias forces between the thermal interface material and the substrate based on material properties of the unitary body.

19. A method of fabricating an integrated device package, the method comprising:
coupling a die to a substrate;
coupling a thermal interface material to the die; and
coupling a lid to the substrate and to the thermal interface material, the lid comprising a unitary body including one or more openings defining a die contact area of the unitary body and one or more compliant members of the unitary body.

20. The method of claim 19, further comprising electrically coupling the substrate to a printed circuit board.
